(19) United States
(12) Patent Application Publication
(10) Pub. No.: US 2025/0169177 A1
(43) Pub. Date: May 22, 2025

(54) BACKSIDE CONTACT WITH STRAIGHT PROFILE

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Chih-Chao Yang, Glenmont, NY (US)

(21) Appl. No.: 18/511,334

(22) Filed: Nov. 16, 2023

(51) Int. Cl. H01L 27/12

(52) U.S. Cl. CPC H10D 86/0214; H10D 86/441; H10D 86/60

(57) ABSTRACT

A method for fabrication of a semiconductor device includes forming a sacrificial dielectric layer in a trench over a dielectric liner, forming an inner spacing layer on the sacrificial dielectric layer and an additional dielectric layer over the inner spacing layer. Contact openings are patterned in the additional dielectric layer down to the inner spacing layer. A breaking through etch is performed on the inner spacing layer in accordance with the contact openings to expose the sacrificial dielectric layer and to expose a thickness of the inner spacing layers within the contacts openings. The thickness of the inner spacing layer is treated to form inner spacers in sidewalls of the contact openings. Etching to remove the sacrificial dielectric layer from the contact openings is performed wherein the inner spacers in sidewalls of the contact openings protect the sidewalls from tapering during the etching. Contacts are formed in the contact openings.

### BACKGROUND

The present invention generally relates to semiconductor devices and processing methods, and more particularly to stacked field effect transistors (FETs) with contacts formed using inner spacers to preserve profile features.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

Active regions formed by epitaxial growth processes have increasingly become smaller in size. As a result, contacts to the epitaxial regions shrink as well as spacings between contacts. During a contact open process, contact openings are made through a dielectric layer. With reduced spacings, dielectric walls separating the contacts are diminished and can be a source of charge leakage or failures due to inadequate dielectric isolation between the adjacent contacts.

Therefore a need exists for methods and devices that improve dielectric isolation between contacts. A further need exists for preserving a contact profile to ensure adequate contact metal to reduce contact resistance.

### SUMMARY

In accordance with an embodiment of the present invention, a method for fabrication of a semiconductor device includes forming a sacrificial dielectric layer in a trench over a dielectric liner, forming an inner spacing layer on the sacrificial dielectric layer and an additional dielectric layer over the inner spacing layer. Contact openings are patterned in the additional dielectric layer down to the inner spacing layer. A breakthrough etch is performed on the inner spacing layer in accordance with the contact openings to expose the sacrificial dielectric layer and to expose a thickness of the inner spacing layers within the contacts openings. The thickness of the inner spacing layer is treated to form inner spacers in sidewalls of the contact openings. Etching to remove the sacrificial dielectric layer from the contact openings is performed wherein the inner spacers in sidewalls of the contact openings protect the sidewalls from tapering during the etching. Contacts are formed in the contact openings.

In accordance with another embodiment of the present invention, a method for fabrication of a semiconductor device includes removing a substrate to expose a dielectric liner covering shallow trench isolation (STI) regions and to expose sacrificial placeholders associated with active regions; forming a sacrificial dielectric layer over the dielectric liner and the sacrificial placeholders; forming an inner spacing layer on the sacrificial dielectric layer; forming an additional dielectric layer over the inner spacing layer; patterning contact openings in the additional dielectric layer down to the inner spacing layer; breaking through the inner spacing layer in accordance with the contact openings to expose the sacrificial dielectric layer and to expose a thickness of the inner spacing layers within the contacts openings; treating the thickness of the inner spacing layer to form inner spacers in sidewalls of the contact openings; etching to remove the sacrificial dielectric layer and the sacrificial placeholders from the contact openings wherein the inner spacers in sidewalls of the contact openings protect the sidewalls from tapering during the etching; and forming contacts in the contact openings.

In other embodiments, the inner spacing layer includes a semiconductor material. The semiconductor material can include an amorphous phase of silicon. The thickness of the inner spacing layer can be treated to form inner spacers by nitriding the thickness of the inner spacing layer to form silicon nitride inner spacers. The trench is disposed between shallow trench isolation (STI) regions and a dielectric liner lines the trench over the STI regions. The sacrificial dielectric layer is selectively removeable relative to the dielectric liner and the inner spacers. In one embodiment, a substrate is removed to expose the dielectric liner. The contacts correspond with active regions and adjacent contacts connect to active regions having opposite conductivities.

In accordance with another embodiment of the present invention, a semiconductor device includes a dielectric liner lining shallow trench isolation regions, an inner spacing layer and an interlevel dielectric layer in contact with the inner spacing layer. Contacts are formed through the interlevel dielectric layer and through the inner spacing layer and in contact with the dielectric liner. The contacts include a straight profile through the interlevel dielectric layer as delineated by inner spacers formed within the inner spacings layer and within the straight profile.

In other embodiments, the inner spacing layer includes a semiconductor material. The inner spacers can include silicon nitride. The contacts can correspond with active regions and adjacent contacts connect to active regions having opposite conductivities.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor substrate having active regions with different conductivities, in accordance with an embodiment of the present invention;

FIG. 2 shows a cross-sectional view with the substrate removed, in accordance with an embodiment of the present invention;

FIG. 3 shows a cross-sectional view with a sacrificial dielectric layer formed in a trench lined with a dielectric liner and planarized to deposit an inner spacing layer, in accordance with an embodiment of the present invention;

FIG. 4 shows a cross-sectional view having an interlevel dielectric layer patterned down to the inner spacing layer using a patterning mask, in accordance with an embodiment of the present invention;

FIG. 5 shows a cross-sectional view with a break through to the inner spacing layer and treatment of exposed portions of the inner spacing layer to form inner spacers, in accordance with an embodiment of the present invention;

FIG. 6 shows a cross-sectional view with the sacrificial dielectric layer removed and a straight contact profile preserved in accordance with the inner spacers, in accordance with an embodiment of the present invention;

FIG. 7 shows a cross-sectional view with contact openings filled to form straight profile contacts, in accordance with an embodiment of the present invention;

FIG. 8 shows cross-sectional views, taken at section lines Y2, Y1, X1, depicting different views of a semiconductor device with straight profile contacts and inner spacers, in accordance with an embodiment of the present invention; and

FIG. 9 shows a flow chart for methods for fabricating a semiconductor, in accordance with an embodiment of the present invention.

### DETAILED DESCRIPTION

In accordance with embodiments of the present invention, devices and methods are described which employ inner spacers to protect portions of an interlevel dielectric layer during the etching of contact openings. The inner spacers maintain lithographic dimensions during etch processes that are employed to form the contact openings. As a result, a straight contact profile is preserved during etching by the inner spacers. This later enables a shape of the contact that provides adequate conduction after a conductive fill. The contact possesses a straight profile that exhibits minimal tapering and includes nearly vertical sidewalls (e.g., within less than 10 degrees of vertical, and preferably less than 5 degrees).

A contact profile in accordance with embodiments of the present invention does not suffer from etching fanout or tapering which results in an increase in size of the contact opening at its entrance. Such fanout can also result in a reduction in size or inadequate dielectric isolation between adjacent contacts. However, in accordance with the embodiments of the present invention, this fanout is minimized and the patterned dimensions of the contact openings are vertically maintained during etching of the contact openings. The preservation of the contact openings provides for an improved contact profile that further ensures adequate contact performance as the contacts have adequate dielectric between them and fanout is eliminated which can result in the contacts being too close and shorting.

In embodiments of the present invention, a semiconductor device includes inner spacers which are interposed within an interlevel dielectric layer. An inner spacing layer is formed and can act as an etch stop layer. The inner spacing layer is exposed and broken through. The inner spacers are self-aligned since once contact openings are formed portions of the inner spacing layer exposed by the breakthrough of the inner spacing layer are treated to form etch resistant dielectric materials. Once formed, the inner spacers resist dimensional loss or fanout of the contact openings. Well-formed contact openings provide improved contact profiles once the contact metal is deposited therein. Contacts are formed without fanout tails and sufficient dielectric isolation between adjacent contacts.

In one embodiment, the inner spacers can be provided for source/drain (S/D) contacts for n-type field effect transistors (NFET) or for p-type field effect transistors (PFET). The NFETs and PFETs can be included in a stacked FET device, although inner spacers can be employed in other devices and for other contact types.

In embodiments of the present invention, a method for fabrication of a semiconductor device includes forming a sacrificial dielectric layer in a trench over a dielectric liner and forming an inner spacing layer on the sacrificial dielectric layer. An additional dielectric layer is formed over the inner spacing layer and contact openings are patterned in the additional dielectric layer down to the inner spacing layer. The inner spacing layer is broken through in accordance with the contact openings to expose the sacrificial dielectric layer and to expose a thickness of the inner spacing layer within the contact openings. The thickness of the inner spacing layer is treated to form inner spacers in sidewalls of the contact openings. The sacrificial dielectric layer is etched to remove it from the contact openings where the inner spacers in sidewalls of the contact openings protect the sidewalls from tapering during the etching. Contacts are formed in the contact openings. The contacts include a straight profile that prevents tapering and therefor short circuiting between the contacts.

In another embodiment, a method for fabrication of a semiconductor device includes removing a substrate to expose a dielectric liner covering shallow trench isolation (STI) regions and to expose sacrificial placeholders associated with active regions, forming a sacrificial dielectric layer over the dielectric liner and the sacrificial placeholders and forming an inner spacing layer on the sacrificial dielectric layer. An additional dielectric layer is formed over the inner spacing layer and contact openings are patterned in the additional dielectric layer down to the inner spacing layer. The inner spacing layer is broken through in accordance with the contact openings to expose the sacrificial dielectric layer and to expose a thickness of the inner spacing layer within the contact openings. The thickness of the inner spacing layer is treated to form inner spacers in sidewalls of the contact openings. The sacrificial dielectric layer and the sacrificial placeholders are etched from the contact openings wherein the inner spacers in sidewalls of the contact openings protect the sidewalls from tapering during the etching. Contacts are formed in the contact openings.

In some embodiments, the inner spacing layer includes a semiconductor material, e.g., an amorphous phase of silicon. This material can react to nitrogen to form a silicon nitride, which is resistant to etching and assist in maintaining the contact profile. Treating the thickness of the inner spacing layer to form inner spacers can include nitriding the thickness of the inner spacing layer to form silicon nitride inner spacers. The trench can be disposed between shallow trench isolation (STI) regions and a dielectric liner that lines the trench over the STI regions. The sacrificial dielectric layer can be selectively removeable relative to the dielectric liner and the inner spacers. A substrate can be removed to expose the dielectric liner, e.g., in stacked FET device. The contacts can correspond with active regions, and adjacent contacts can connect to active regions having opposite conductivities. In situations where different device types (e.g., NFETs and PFETs) are adjacent, the straight contacts are particularly useful and short circuiting in these situations can be more detrimental since opposite conductivity devices could be undesirably activated.

Semiconductor devices formed in accordance with embodiments of the present invention includes a dielectric liner lining shallow trench isolation regions, an inner spacing layer and an interlevel dielectric layer in contact with the inner spacing layer. Contacts are formed through the interlevel dielectric layer and through the inner spacing layer and in contact with the dielectric liner. The contacts include a straight profile through the interlevel dielectric layer as delineated by inner spacers formed within the inner spacing layer and within the straight profile.

In some embodiments, the inner spacing layer can include a semiconductor material and can be treated to become, e.g., silicon nitride. The contacts can correspond with active regions and adjacent contacts can connect to active regions having opposite conductivities.

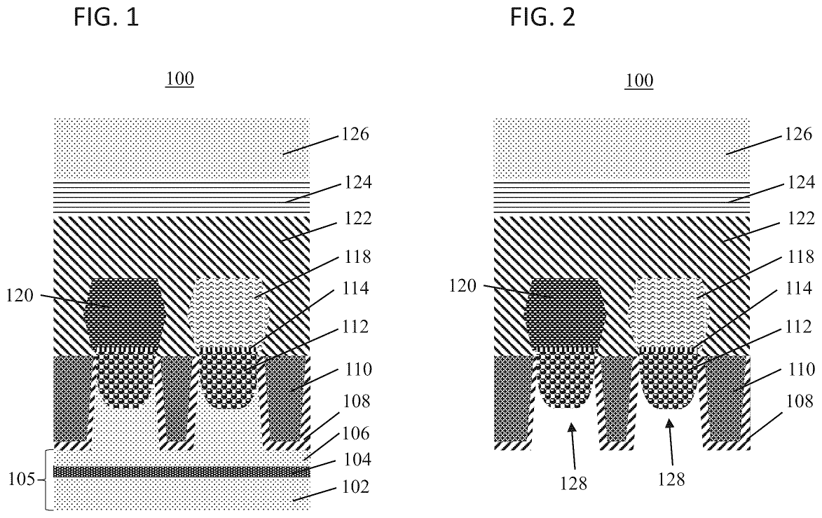

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 105 having multiple layers on which the stacked FET device will be fabricated. FIG. 1 depicts a cross-sectional view of a partially fabricated stacked FET device. It should be understood that other types of devices and architectures can be employed and benefit in accordance with embodiments of the present invention.

The substrate 105 can include any suitable substrate structure, e.g., a bulk semiconductor, a semiconductor-on-insulator (SOI) substrate, etc., and preferably includes a monocrystalline semiconductor. In one example, the substrate 105 can include a silicon-containing material. Illustrative examples of Si-containing materials suitable for the substrate 105 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 104 formed within the substrate 105 separates substrate portions 102 and 106. The etch stop layer 104 can include an epitaxially grown crystal structure. The etch stop layer 104 includes a material that permits the selective etching and removal of the substrate portion 102 in later steps. In one embodiment, the etch stop layer 104 includes SiGe although depending on the material of the substrate 105, other materials can be selected, e.g., SiGeC, SiC, etc. The substrate portion 102 can include a same material as the substrate portion 106, although other semiconductor materials can be employed, e.g., SiGe, SiGeC, SiC, etc.

A layer stack or stacks (not shown) are applied to or formed on the substrate portion 106. In one embodiment, one or more nanosheets (NS) are applied to the substrate portion 106. In another embodiment, the layer stacks can be epitaxially grown using different chemistries to form layers having different properties. The nanosheet or sheets can be patterned to expose and etch the substrate portion 106.

Substrate portion 106 is etched to form trenches which are lined with dielectric liner 108 and filled to form shallow trench isolation (STI) or STI regions 110. Dielectric liner 108 and STI regions 110 can be formed by depositing dielectric material, such as, e.g., SiN, SiOₓN_{y}, SiCO or other suitable compounds using, e.g., chemical vapor deposition (CVD), although other deposition methods can be employed. Dielectric liner 108 preferably includes a material that provides etch selectivity with later formed interlevel dielectric layers.

Processing continues with front end of line processing (FEOL), middle end of the line (MOL) and backend of the line (BEOL) fabrication. Sacrificial placeholders 112, active regions 118, 120, gates (not shown), interlevel dielectric layer 122 and contacts and other structures are formed by a number of processes. For example, the gates can be formed using a dummy gate replacement method. The dummy gate material can include a polysilicon, amorphous Si or other selectively removeable material. The regions of the dummy gates have a high dielectric constant (high-K) gate dielectric formed. The dummy gate materials is removed and replaced by a gate metal fill. This process is known as a High-K Metal Gate (HKMG) process to form a gate structure for selectively activating FETs.

The sacrificial placeholders 112 can be epitaxially grown in substrate portion 106. The sacrificial placeholder 112 can include SiGe or other epitaxial grown material that can be selectively removed relative to surrounding materials. A bottom dielectric interface (BDI) 114 remains after processing the nanosheets.

An epitaxial growth process is performed to form active regions 118 and 120. The active regions 118, 120 can be employed for top or bottom FETs in stacked FET devices. Active regions 118 and 120 are employed to form source and drain (S/D) regions for transistors of the device under construction. Active regions 118 and 120 can include doped Si or SiGe and include faceted surfaces when epitaxial growth is not confined. In one embodiment, the active regions 118 and 120 can be designated as P-type or N-type devices, respectively. The P-type and N-type devices can have different materials selected for the active regions 118 and 120. For example, if the active region 118 is a PFET, boron doped SiGe can be employed. For example, if the active region 120 is an NFET, phosphorous doped Si can be employed. The active regions 118 and 120 can be appropriately doped during the formation of the active regions 118 and 120, e.g., during epitaxial growth. It should be understood that other dopants and materials can be employed for the active regions 118 and 120. As shown, P-type and N-type devices can be formed adjacent to one another. Processing could include forming one device type and then the other device type by employing block masks to protect each device during processing of the other. In other embodiments, device types having a same conductivity can be formed adjacent to one another,

A dielectric layer 122, such as, e.g., an interlevel dielectric layer (ILD) is formed. The dielectric layer 122 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 122 can be deposited using CVD, although other deposition methods can be employed.

MOL contacts (not shown) can be formed to make connections with the active regions 118 and 120 from a top side. Trenches or holes are formed through a top side in the dielectric layer 122 to expose the active regions 118 and 120. In useful embodiments, a silicide liner, such as Ti, Ni, NiPt is deposited first, then a diffusion barrier can be formed in the trenches prior to a conductive fill. The diffusion barrier can include, e.g., TiN, TaN, or similar materials. A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form topside S/D contacts.

Processing continues with the formation of back end of the line (BEOL) layer 124, which can include metal structures that connect to the topside S/D contacts and dielectric layers to complete the side for the stacked FET device and provide electrical access to the devices formed. A carrier wafer 126 can be bonded to the BEOL layer 124. The carrier wafer 126 provides support and transportability to the wafer 100 for further processing which includes flipping the wafer 100 for processing the other side (bottom) of the stacked FET device.

Referring to FIG. 2, to continue processing, the wafer 100 can be flipped to process features on the bottom side of the stacked FET device. However, for clarity and consistency, the stacked FET device will be shown in the FIGS. in a same orientation as previously described with continued and consistent reference to bottom/top. The substrate portion 102 is removed from the bottom side of the stacked FET device. The substrate portion 102 can be removed by an etch process that stops on the etch stop layer 104. In an alternate embodiment, a cleave process can be employed to propagate a crack to remove the substrate portion 102 at the etch stop layer 104.

The etch stop layer 104 is then removed by an etch process. In an alternate embodiment, a chemical mechanical polish (CMP) process can be employed. With the removal of the etch stop layer 104, the substrate portion 106 is exposed. The substrate portion 106 is also removed by an etch process that selectively removes the material of the substrate portion 106 relative to the dielectric liner 108 and the sacrificial placeholders 112. The removal of the substrate portion 106 leaves openings 128 with the sacrificial placeholders 112 exposed.

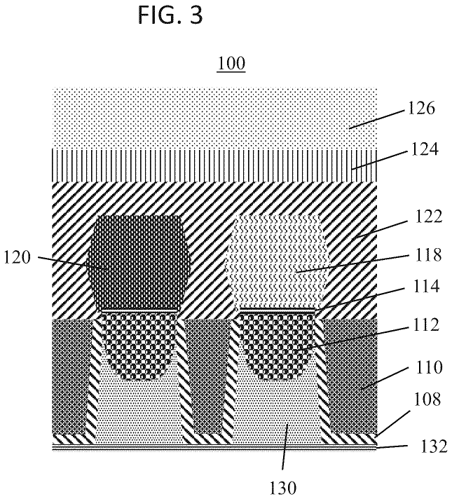

Referring to FIG. 3, a sacrificial dielectric layer 130 is formed over the dielectric liner 108 and the sacrificial placeholders 112. The dielectric layer 130 includes a material that is selectively removeable relative to the dielectric liner 108. For example, if the dielectric liner 108 includes a silicon nitride or silicon oxynitride, dielectric layer 130 can include a silicon oxide and be selectively etchable with respect to the dielectric liner 108. The dielectric layer 130 can include the same materials as dielectric layer 122. A CMP process can be employed to planarize the free surface of the dielectric layer 130.

An inner spacing layer 132 is deposited over the planarized surface of the dielectric liner 108 and dielectric layer 130. The inner spacing layer 132 can include a material that is selectively removable relative to the dielectric layer 130. The inner spacing layer 132 can include a dielectric material, e.g., an undoped semiconductor material. In a particularly useful embodiment, the inner spacing layer 132 includes an amorphous phase of Si. The inner spacing layer 132 can be applied using a CVD process, although physical vapor deposition (PVD), atomic layer deposition (ALD) or other deposition processes can be employed.

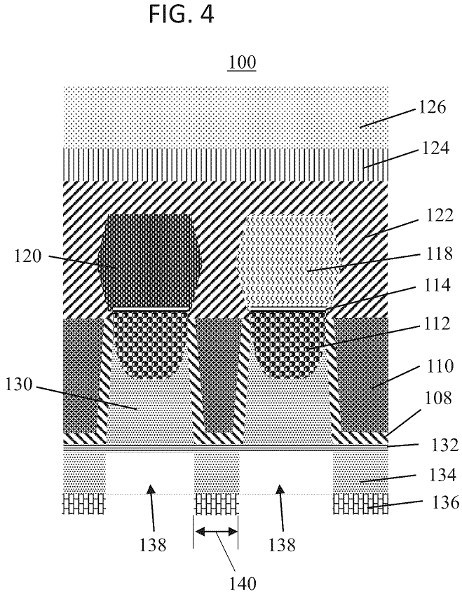

Referring to FIG. 4, an additional dielectric layer 134 (e.g., an interlevel dielectric layer) is formed over the inner spacing layer 132. The additional dielectric layer 134 includes a material that is selectively removeable relative to the inner spacing layer 132. The additional dielectric layer 134 can include the same materials as dielectric layer 130. A CMP process can be employed to planarize the free surface of the additional dielectric layer 134.

A patternable material, such as, e.g., a photoresist or hard mask 136 is deposited or spun onto a surface of the wafer 100 over the additional dielectric layer 134. In one embodiment, an anti-reflective coating (ARC) layer (not shown) may be formed on the additional dielectric layer 134 followed by the photoresist 136 formed on the ARC layer. The photoresist 136 can be imaged with an image pattern and developed to form an etch mask. Due to the size and spacing of the active regions 118, 120, openings 138 need to be sized to permit lithographic patterning and permit sufficient space for dielectric isolation between adjacent contacts.

The additional dielectric layer 134 can be etched in accordance with the etch mask of photoresist 136 to create openings 138 that expose the inner spacing layer 132, which functions as an etch stop layer. The openings 138 are accurately controlled by an anisotropic etch, e.g., a reactive ion etch (RIE) etch or ion beam etch (IBE etch). The anisotropic etch, such as a plasma dry etch, provides accurate control of spacing 140 between future-formed contacts, for example, in accordance with the lithographic process overlay error of three standard deviations is less than 5 nm.

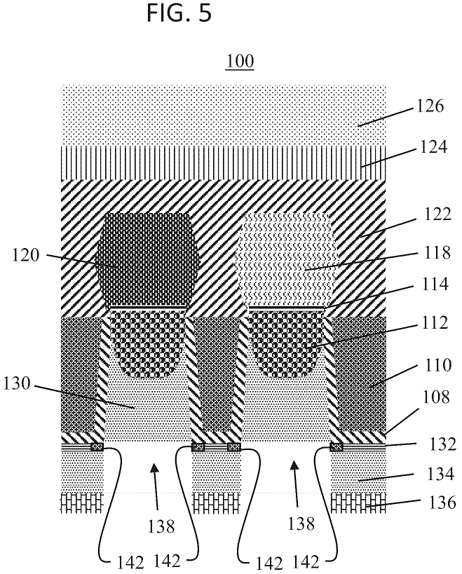

Referring to FIG. 5, a breakthrough etch is performed selectively to the dielectric layer 130 to open up the inner spacing layer 132 in accordance with the photoresist 136 and expose the underlying dielectric layer 130. The breakthrough etch can include an anisotropic etch, e.g., RIE or IBE etch. The breakthrough etch exposes a thickness of the inner spacing layer 132 at sidewalls of the openings 138.

In one embodiment, amorphous Si (a-Si) is employed for the inner spacing layer 132. The exposed portions are exposed to a nitridation process to convert exposed portions of the inner spacing layer 132 to silicon nitride (e.g., Si₃N₄) and form inner spacers 142. The silicon can be exposed to ionized nitrogen gas, with nitridation commencing at about 1150° C. The nitrogen diffuses into the Si beyond the end portions of the inner spacing layer 132 which adds some width to the inner spacers 142. The formation of the inner spacers 142 is a self-aligned process, so that the inner spacers 142 are formed within sidewalls of the openings 138 only where the inner spacing layer 132 has been exposed. The inner spacers 142 preserve dimensions of the contact openings 138 in a next etch step. It should be understood that other processes and materials are also contemplated to form inner spacers 142.

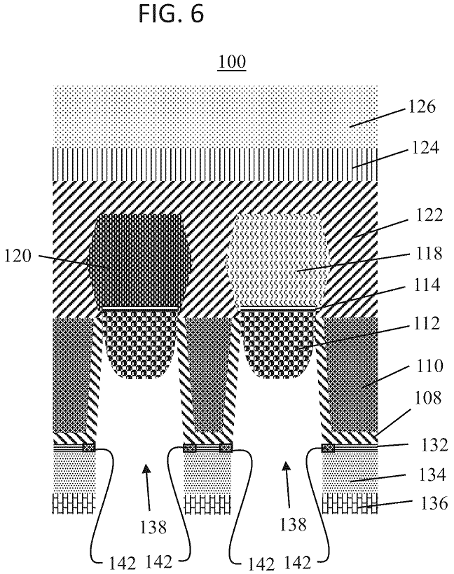

Referring to FIG. 6, dielectric layer 130 is removed by an anisotropic etch process, such as, e.g., RIE. The etch process removes material of dielectric layer 130 in accordance with photoresist 136 and selectively with respect to dielectric liner 108, the sacrificial placeholders 112 and inner spacers 142. The inner spacers 142 are positioned at a location where the RIE process would begin to cut into the sidewalls of the additional dielectric layer 134. The inner spacers 142 maintain the vertical sidewall profile for openings 138. Without the inner spacers 142 the sidewall profile of the additional dielectric layer 134 for the openings 138 would taper or fanout, which would result in the expansion of the openings 138 at the mouth. This taper would reduce the dielectric material between expanded sized adjacent contacts and thus make space between contacts very narrow.

Instead, in accordance with the embodiments of the present invention, better profile control for contacts openings 138 is preserved. The straight profile of the openings includes a consistent width that ensures adequate dielectric isolation of adjacent contacts. In addition, the presence of inner spacers 142 increases process tolerance since greater leeway is afforded the etching processes since concerns about tapered holes is alleviated.

Etching can continue with the removal of the sacrificial placeholders 112 and BDI 114 to expose the active regions 118 and 120. A pre-silicide clean process can be performed to clean surfaces in preparation for siliciding exposed surfaces of the active regions 118, 120. The photoresist 136 is removed from the wafer 100.

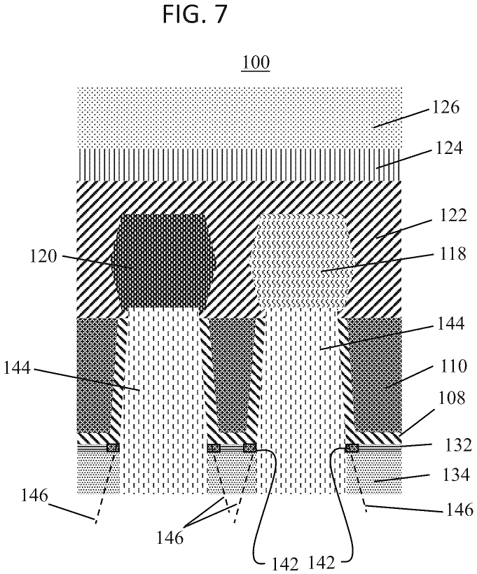

Referring to FIG. 7, in useful embodiments, a silicide liner, such as Ti, Ni, NiPt is deposited first, then a diffusion barrier can be formed in the contact openings 138 (FIG. 6) prior to a conductive fill. The diffusion barrier can include, e.g., TiN, TaN, or similar materials. A conductive fill is performed to fill the contact openings 138. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form contacts 144. Contacts 144 directly connect to active region 118 for a PFET and active region 120 for an adjacent NFET.

Dotted lines 146 are included to show taper angles that would be formed in the additional dielectric layer 134 if inner spacers 142 in accordance with embodiments of the present invention were not present during the etching of the contact openings 138 (FIG. 6). Especially in situations where NFETs and PFETs are adjacent, contacts 144 need to be independent and not shorted to one another, and crosstalk needs to be minimized.

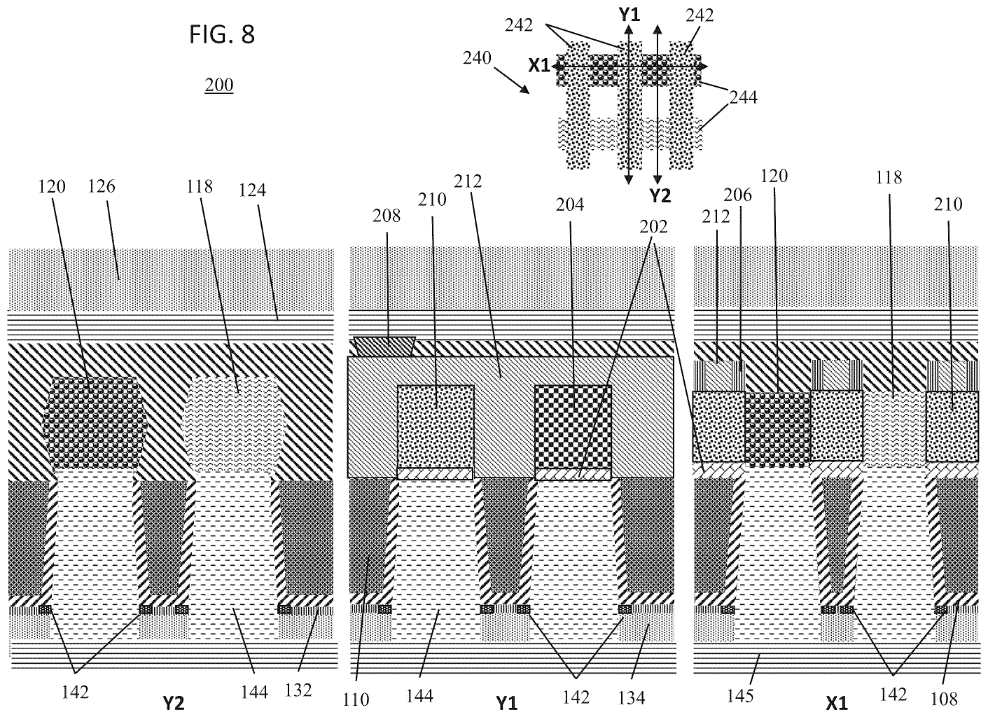

Processing can continue with the formation of a backside interconnect layer 145 (FIG. 8), which will be employed to form metal structures and dielectric layers to complete the bottom side of the stacked FET device and provide electrical access to the devices formed. The backside interconnect layer 145 can be employed to form backside power rails (BPR) for a backside power distribution network. The backside interconnect layer 145 connects directly to the backside contacts 144.

Referring to FIG. 8, a stacked FET device 200 is provided having FETs formed in at least two layers. A semiconductor device such as stacked FET device 200 includes a stacked transistor structure having field effect transistors on at least two levels. The at least two levels include a top side and bottom side. A top view is shown in an inset 240. Inset 240 shows active regions 244 and gate lines 242. Transistor channels are formed at intersections between active regions 244 and gate lines 242. Inset 240 shows cross-section lines Y2, Y1 and X1 through the stacked FET device 200. Cross-sectional views Y2, Y1 and X1 are shown that correspond with section lines Y2, Y1 and X1.

Active regions 244 correspond in the cross-section views with active regions 118 and 120. Gate lines 242 correspond with replacement metal gate (RMG) 212 and nanosheet gate structures 204, 210. Contacts 144 are isolated from the nanosheet gate structures 204 and 210 by bottom dielectric interfaces (BDI) 202. Portions of the RMG 212 include dielectric spacers 206. A gate contact 208 connects RMG to circuitry in the BEOL layer 124.

Inner spacers 142 can be employed for both topside and bottom side contacts for FETs. The use of inner spacers 142 with a stacked FET is for illustration purposes; however, inner spacers 142 can also be employed for single level devices, and can be employed for any layer or contact type. The backside interconnect layer 145 can be processed to form buried rails and/or other metal structure(s) that are formed to connect with contacts 144.

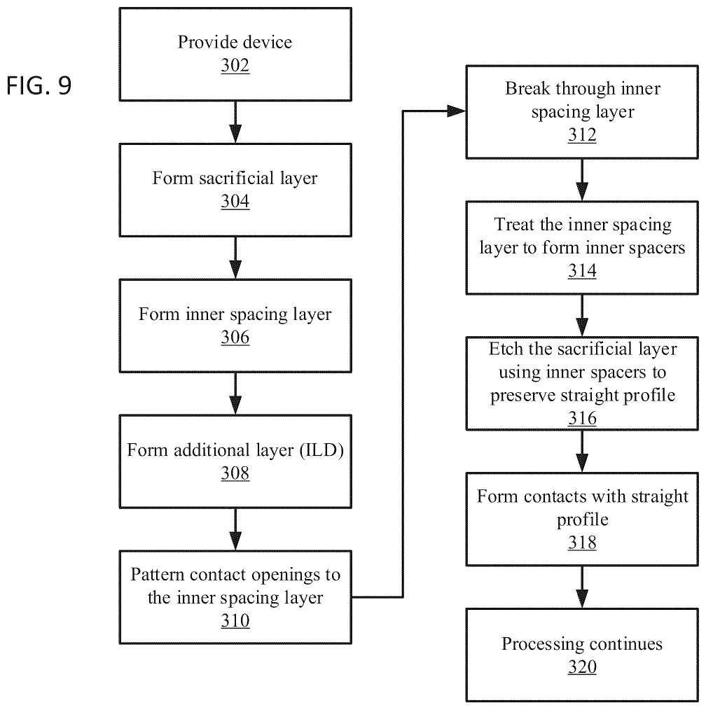

Referring to FIG. 9, methods for fabrication of a semiconductor device are described. In block 302, a semiconductor device is fabricated to a point where contacts need to be formed. This can include front end of the line (FOL), middle end of the line (MOL) or back end or line (BEOL) processing. In one embodiment, active regions are provided that need to be connected to by contacts.

In block 304, a sacrificial dielectric layer is formed in a trench over a dielectric liner. The trench can be formed between STI regions (which can be lined with the dielectric liner). In one embodiment, the sacrificial layer can also be formed over sacrificial placeholders associated with epitaxial regions (e.g., S/D region) of active regions.

In block 306, an inner spacing layer is formed on the sacrificial dielectric layer. In one embodiment, the inner spacing layer can include a semiconductor material, and in particular an amorphous phase of silicon.

In block 308, an additional dielectric layer is formed over the inner spacing layer. In one embodiment, the additional dielectric layer can include an interlevel dielectric layer.

In block 310, contact openings are patterned in the additional dielectric layer down to the inner spacing layer. The inner spacing layer can function as an etch stop.

In block 312, a breakthrough etch is performed to break through the inner spacing layer in accordance with the contact openings to expose the sacrificial dielectric layer and to expose a thickness of the inner spacing layers within the contacts openings.

In block 314, the thickness of the inner spacing layer is treated in a self-aligned treatment process to form inner spacers in sidewalls of the contact openings. In one embodiment, the thickness of the inner spacing layer is treated in a nitriding process to form silicon nitride inner spacers.

In block 316, etching is performed to remove the sacrificial dielectric layer from the contact openings wherein the inner spacers in sidewalls of the contact openings protect the sidewalls from tapering during the etching to preserve a straight sidewall profile.

In block 318, contacts are formed in the contact openings. The contacts include a straight vertical profile that improves dielectric isolation between the contacts. In useful embodiments, processing can continue, in block 320, with the formation of back end of line (BEOL) structures, removal of the carrier wafer and the completion of the device.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for fabrication of a semiconductor device, comprising:
forming a sacrificial dielectric layer in a trench over a dielectric liner;
forming an inner spacing layer on the sacrificial dielectric layer;
forming an additional dielectric layer over the inner spacing layer;
patterning contact openings in the additional dielectric layer down to the inner spacing layer;
breaking through the inner spacing layer in accordance with the contact openings to expose the sacrificial dielectric layer and to expose a thickness of the inner spacing layer within the contact openings;
treating the thickness of the inner spacing layer to form inner spacers in sidewalls of the contact openings;
etching to remove the sacrificial dielectric layer from the contact openings wherein the inner spacers in sidewalls of the contact openings protect the sidewalls from tapering during the etching; and
forming contacts in the contact openings.

2. The method as recited in claim 1, wherein forming the inner spacing layer includes forming the inner spacing layer from a semiconductor material.

3. The method as recited in claim 2, wherein the semiconductor material includes an amorphous phase of silicon.

4. The method as recited in claim 2, wherein treating the thickness of the inner spacing layer to form inner spacers includes nitriding the thickness of the inner spacing layer to form silicon nitride inner spacers.

5. The method as recited in claim 1, wherein the trench is disposed between shallow trench isolation (STI) regions and a dielectric liner lines the trench over the STI regions.

6. The method as recited in claim 1, wherein the sacrificial dielectric layer is selectively removeable relative to the dielectric liner and the inner spacers.

7. The method as recited in claim 1, further comprising removing a substrate to expose the dielectric liner.

8. The method as recited in claim 1, wherein the contacts correspond with active regions and adjacent contacts connect to active regions having opposite conductivities.

9. A method for fabrication of a semiconductor device, comprising:
removing a substrate to expose a dielectric liner covering shallow trench isolation (STI) regions and to expose sacrificial placeholders associated with active regions;
forming a sacrificial dielectric layer over the dielectric liner and the sacrificial placeholders;
forming an inner spacing layer on the sacrificial dielectric layer;
forming an additional dielectric layer over the inner spacing layer;
patterning contact openings in the additional dielectric layer down to the inner spacing layer;
breaking through the inner spacing layer in accordance with the contact openings to expose the sacrificial dielectric layer and to expose a thickness of the inner spacing layer within the contact openings;
treating the thickness of the inner spacing layer to form inner spacers in sidewalls of the contact openings;
etching to remove the sacrificial dielectric layer and the sacrificial placeholders from the contact openings wherein the inner spacers in sidewalls of the contact openings protect the sidewalls from tapering during the etching; and
forming contacts in the contact openings.

10. The method as recited in claim 9, wherein forming the inner spacing layer includes forming the inner spacing layer from a semiconductor material.

11. The method as recited in claim 10, wherein the semiconductor material includes an amorphous phase of silicon.

12. The method as recited in claim 10, wherein treating the thickness of the inner spacing layer to form inner spacers includes nitriding the thickness of the inner spacing layer to form silicon nitride inner spacers.

13. The method as recited in claim 9, wherein the sacrificial dielectric layer is selectively removeable relative to the dielectric liner and the inner spacers.

14. The method as recited in claim 9, further comprising removing a substrate to expose the dielectric liner.

15. The method as recited in claim 9, wherein the contacts correspond with active regions and adjacent contacts connect to active regions having opposite conductivities.

16. The method as recited in claim 9, wherein the contacts include backside contacts to source/drain regions of a stacked field effect transistor device.

17. A semiconductor device, comprising:
a dielectric liner lining shallow trench isolation regions;
an inner spacing layer;
an interlevel dielectric layer in contact with the inner spacing layer; and
contacts formed through the interlevel dielectric layer and through the inner spacing layer and in contact with the dielectric liner;
the contacts including a straight profile through the interlevel dielectric layer as delineated by inner spacers formed within the inner spacing layer and within the straight profile.

18. The semiconductor device as recited in claim 17, wherein the inner spacing layer includes a semiconductor material.

19. The semiconductor device as recited in claim 17, wherein the inner spacers include silicon nitride.

20. The semiconductor device as recited in claim 17, wherein the contacts correspond with active regions and adjacent contacts connect to active regions having opposite conductivities.
